(19) United States
(12) Patent Application Publication
(10) Pub. No.: US 2015/0214426 A1
(43) Pub. Date: Jul. 30, 2015

(54) LIGHT-EMITTING DEVICE

(71) Applicant: Wen-Ching Hung, Hsinchu City (TW)

(72) Inventor: Wen-Ching Hung, Hsinchu City (TW)

(73) Assignee: RIGIDCRYSTAL TECHNOLOGY CO., LTD, Hsinchu City (TW)

(21) Appl. No.: 14/572,797

(22) Filed: Dec. 17, 2014

(30) Foreign Application Priority Data
Jan. 29, 2014 (TW) 103103598

(51) Int. Cl. H01L 33/06; H01L 33/32

(52) U.S. Cl. CPC H01L 33/06; H01L 33/32

(57) ABSTRACT

A light-emitting device including a first type doped semiconductor layer, a second type doped semiconductor layer, and a light-emitting layer is provided. The light-emitting layer is located between the first type doped semiconductor layer and the second type doped semiconductor layer. The light-emitting layer includes a plurality of barrier layers and a plurality of quantum well layers. Each of the quantum well layers is located between two adjacent barrier layers, and the quantum well layers include a germanium dopant.

### CROSS-REFERENCE TO RELATED APPLICATION

This application claims the priority benefit of Taiwan application serial no. 103103598, filed on Jan. 29, 2014. The entirety of the above-mentioned patent application is hereby incorporated by reference herein and made a part of this specification.

### FIELD OF THE INVENTION

The invention relates to a light-emitting device and more particularly to a light-emitting device including multiple quantum wells.

### Description of Related Art

A light-emitting diode (LED) is a semiconductor device that is applicable to a light-emitting apparatus. Since the LED is characterized by low power consumption, low pollution, long service life, fast response speed, and so on, the LED has been extensively applied in a variety of fields, e.g., applied on traffic light, applied on an outdoor billboard, or applied as a backlight source of a display. Hence, the LED has gradually drawn attention from manufacturers in the optoelectronic industry.

Generally, in the LED, an epitaxial layer that includes an n-type doped semiconductor layer, a light-emitting layer, a p-type doped semiconductor layer, and so on is formed on a substrate through metal-organic chemical vapor deposition (MOCVD). During the growth of the light-emitting layer, the wavelength of light emitted from the LED may be changed by adjusting the epitaxial parameters, such as growth pressure, growth temperature, a flow rate of reactive gas (e.g., a flow rate of TMIn), and so forth. According to the related art, the light-emitting layer often includes multiple quantum well layers. The quantum well layers in the light-emitting layer are often made of indium gallium nitride (InGaN), and barrier layers in the light-emitting layer are often made of gallium nitride (GaN). The higher the concentration of the indium content in the quantum well layers, the longer the wavelength of light emitted from the light-emitting layer. By contrast, the lower the concentration of the indium content in the quantum well layers, the shorter the wavelength of light emitted from the light-emitting layer. Hence, when the LED is formed, the concentration of the indium content in the quantum well layers may be adjusted, such that the light-emitting layer is able to emit light with long wavelength, e.g., green light, yellow light, orange light, red light, and so on.

At present, the LED capable of emitting the green light can be formed not only by increasing the flow rate of the reactive gas (i.e., TMIn) to increase the concentration of the indium content in the quantum well layers but also by reducing the growth temperature of the quantum well layers. To be specific, given the high growth temperature, the indium content in the InGaN material is reduced because of the desorption properties of indium atoms and the low decomposition temperature of indium nitride; given the low growth temperature, the impact resulting from the desorption properties of indium atoms and the low decomposition temperature of indium nitride is rather insignificant; therefore, the InGaN material containing the relatively large amount of indium content may be grown when growth temperature is low, and the LED capable of emitting light with the long wavelength can be formed.

Besides, the control of the epitaxial growth temperature of the LED is also a factor that directly affects the indium content in the InGaN material. For instance, the growth temperature at which the LED capable of emitting light with the wavelength of the green light (i.e., about 525 nm) is formed substantially ranges from 690° C. to 735° C. However, if the LED capable of emitting light with long wavelengths, e.g., yellow light (about 560 nm) or orange light (about 620 nm), is to be formed, the growth temperature need be further lowered down, so as to increase the indium content in the quantum well layers. If, however, the growth temperature is overly low, the epitaxial quality of the quantum well layers may be deteriorated; thereby, certain defects may be generated, and the brightness of the emitted light may be drastically reduced; what is worse, the resultant LED may not be able to emit light.

### SUMMARY OF THE INVENTION

The invention is directed to a light-emitting device that is adapted to emit light with the long wavelength and characterized by favorable reliability.

In an embodiment of the invention, a light-emitting device including a first type doped semiconductor layer, a second type doped semiconductor layer, and a light-emitting layer is provided. The light-emitting layer is located between the first type doped semiconductor layer and the second type doped semiconductor layer. The light-emitting layer includes a plurality of barrier layers and a plurality of quantum well layers. Each of the quantum well layers is located between two adjacent barrier layers, and the quantum well layers include a germanium (Ge) dopant.

According to an embodiment of the invention, a material of the quantum well layers includes indium gallium nitride containing the germanium dopant (Ge:InGaN).

According to an embodiment of the invention, a material of the barrier layers includes GaN.

According to an embodiment of the invention, a material of the barrier layers includes indium gallium nitride containing the germanium dopant (Ge:InGaN).

According to an embodiment of the invention, the first type doped semiconductor layer is an n-type doped semiconductor layer, and the second type doped semiconductor layer is a p-type doped semiconductor layer.

According to an embodiment of the invention, the first type doped semiconductor layer is a p-type doped semiconductor layer, and the second type doped semiconductor layer is an n-type doped semiconductor layer.

According to an embodiment of the invention, the light-emitting device further includes a substrate, and the first type doped semiconductor layer is located on the substrate and between the substrate and the light-emitting layer.

According to an embodiment of the invention, the light-emitting device further includes a buffer layer located between the substrate and the first type doped semiconductor layer.

According to an embodiment of the invention, the light-emitting device further includes a first electrode and a second electrode. The first electrode and the first type doped semiconductor layer are electrically connected to each other, and the second electrode and the second type doped semiconductor layer are electrically connected to each other.

According to an embodiment of the invention, the substrate includes an aluminum oxide (Al₂O₃) substrate, a silicon (Si) substrate, a silicon carbide (SiC) substrate, a lithium aluminum oxide (LiAlO₂) substrate, a lithium gallium oxide (LiGaO₂) substrate, a gallium oxide (Ga₂O₃) substrate, a GaN substrate, a gallium phosphide (GaP) substrate, or a gallium arsenide (GaAs) substrate.

According to an embodiment of the invention, light emitted from the light-emitting layer has a wavelength ranging from about 365 nm to about 850 nm.

In view of the above, the germanium dopant in the quantum well layers allows the light-emitting device to emit the light with the long wavelength. Besides, according to an embodiment of the invention, the light-emitting layer may be formed without significantly reducing the growth temperature or on the premise that the original growth temperature is maintained, and thereby the reliability of the light-emitting device may be enhanced.

Several exemplary embodiments accompanied with figures are described in detail below to further describe the invention in details.

### BRIEF DESCRIPTION OF THE DRAWINGS

FIG. 1A is a schematic diagram illustrating a framework of a light-emitting device according to an embodiment of the invention.

FIG. 1B is a schematic diagram illustrating the light-emitting layer depicted in FIG. 1A.

FIG. 1C illustrates components in the light-emitting layer depicted in FIG. 1A.

FIG. 1D is a schematic diagram illustrating a band gap in the light-emitting layer depicted in FIG. 1A.

FIG. 2A illustrates wavelength distribution of a light-emitting device according to an embodiment of the invention.

FIG. 2B illustrates wavelength distribution of a light-emitting device according to another embodiment of the invention.

### DETAILED DESCRIPTION OF DISCLOSED EMBODIMENTS

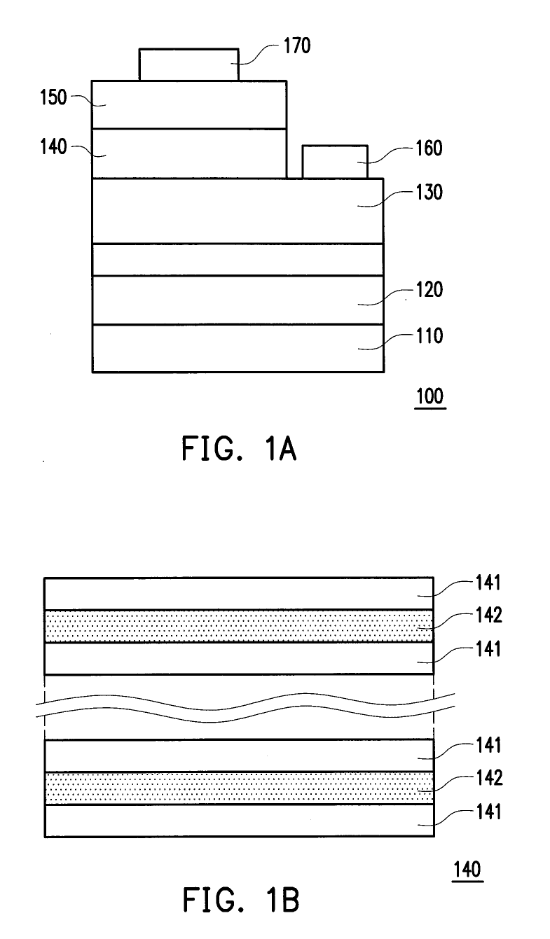

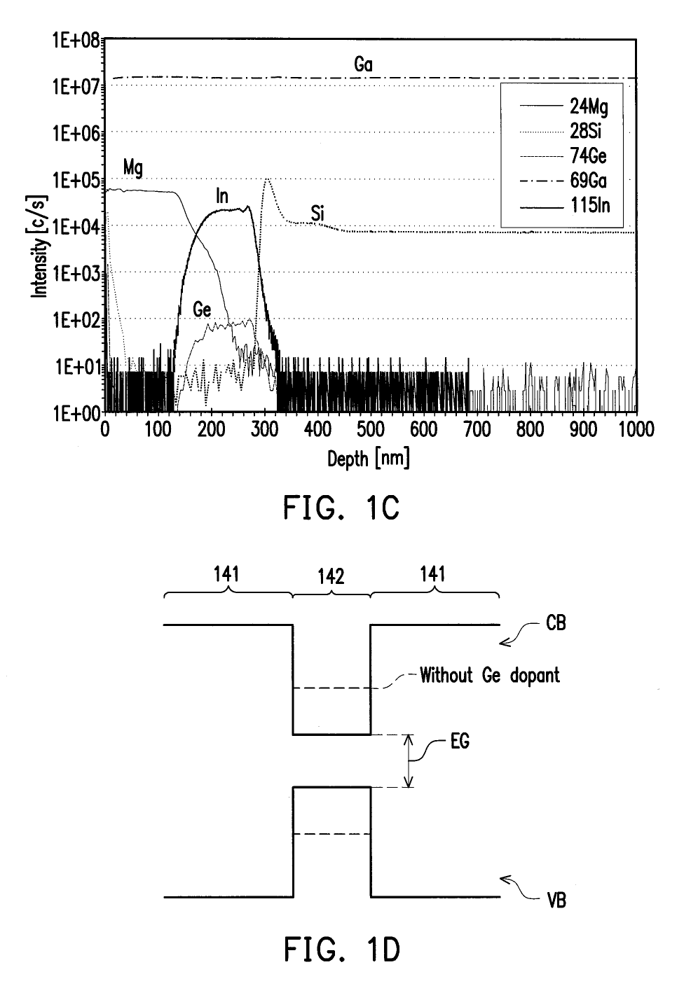

FIG. 1A is a schematic cross-sectional diagram illustrating a light-emitting device according to an embodiment of the invention. With reference to FIG. 1A, the light-emitting device 100 described herein includes a substrate 110, a buffer layer 120, a first type doped semiconductor layer 130, a light-emitting layer 140, and a second type doped semiconductor layer 150. For instance, according to the present embodiment, the substrate 110 may be an Al₂O₃ substrate, a Si substrate, a SiC substrate, a LiAlO₂ substrate, a LiGaO₂ substrate, a gallium oxide (Ga₂O₃) substrate, a GaN substrate, a GaP substrate, or a GaAs substrate. Besides, in the present embodiment, the first type doped semiconductor layer 130 is an n-type doped semiconductor layer, and the second type doped semiconductor layer 150 is a p-type doped semiconductor layer, for instance; however, the invention is not limited thereto. In another embodiment of the invention, the first type doped semiconductor layer 130 may be a p-type doped semiconductor layer, and the second type doped semiconductor layer 150 may be an n-type doped semiconductor layer.

Specifically, in the present embodiment, the buffer layer 120 is located between the substrate 110 and the first type doped semiconductor layer 130. The first type doped semiconductor layer 130 is located over the substrate 110 and between the substrate 110 and the light-emitting layer 140. The light-emitting layer 140 is located between the first type doped semiconductor layer 130 and the second type doped semiconductor layer 150. Additionally, each layer described above is formed over the substrate 110 through MOCVD, which should however not be construed as a limitation to the invention.

FIG. 1B is a schematic diagram illustrating the light-emitting layer depicted in FIG. 1A. FIG. 1C illustrates components in the light-emitting layer depicted in FIG. 1A. FIG. 1D is a schematic diagram illustrating a band gap in the light-emitting layer 140 depicted in FIG. 1A. With reference to FIG. 1B, the light-emitting layer 140 includes a plurality of barrier layers 141 and a plurality of quantum well layers 142. Namely, in the present embodiment, the light-emitting layer 140 has multiple quantum well (MQW) structure, for instance. According to the present embodiment, a material of the quantum well layers 142 includes indium gallium nitride containing the germanium dopant (Ge:InGaN), and a material of the barrier layers 141 includes GaN, for instance. To be more specific, each of the quantum well layers 142 is located between two adjacent barrier layers 141, and the quantum well layers 142 include a germanium (Ge) dopant.

As shown in FIG. 1C, in the light-emitting device, the germanium (Ge) dopant can be clearly observed at the depth of 140 nm to 300 nm. It should be mentioned that the numerical range of each parameter provided above is exemplary and is not intended to limit the scope of the invention.

As shown in FIG. 1D, in the present embodiment, the Ge dopant in the quantum well 142 is conducive to the reduction of the energy gap EG between a conduction band CB and a valance band VB. Note that the Ge dopant mainly serves as the n-type dopant according to the related art, and the Ge dopant is doped into the n-type doped semiconductor layer, so as to increase the carrier concentration of the n-type doped semiconductor layer. However, the Ge dopant described herein is doped into the quantum well layers 142 of the light-emitting layer 140, so as to reduce the energy gap EG between the conduction band CB and the valance band VB and further allow the light-emitting layer to emit light with the long wavelength. In addition, according to the present embodiment, the Ge dopant doped in the quantum well layers 142 of the light-emitting layer 140 allows the growth temperature of the light-emitting layer 140 to stay relatively high.

For instance, in case that the growth temperature of the quantum well layers 142 is around 750° C., the light-emitting layer made of GaN/InGaN pairs can merely emit the blue light of which the wavelength is about 450 nm. Nevertheless, in the present embodiment, given that the growth temperature is around 750° C., the light-emitting layer 140 made of GaN/Ge:InGaN pairs can emit the green light of which the wavelength is about 525 nm. That is, if the same growth temperature is given, or if the grown temperature need not be significantly reduced, the light-emitting layer 140 described herein is allowed to emit light with the relatively long wavelength (e.g., the green light, the yellow light, the orange light, the red light, etc.) by means of the quantum well layers 142 containing the Ge dopant.

Besides, the higher the concentration of the Ge dopant in the quantum well layers 142, the smaller the energy gap EG between the conduction band CB and the valance band VB (as shown in FIG. 1D), and the longer the wavelength of light emitted from the light-emitting layer 140. On the contrary, the lower the concentration of the Ge dopant in the quantum well layers 142, the larger the energy gap EG between the conduction band CB and the valance band VB, and the shorter the wavelength of light emitted from the light-emitting layer 140.

In the present embodiment, the way to adjust the wavelength of light emitted from the light-emitting device 100 by means of the Ge dopant is similar to the way to adjust the wavelength of light emitted from the conventional light-emitting device. Compared to the indium dopant, however, the Ge dopant doped in the quantum well layers 142 prevents the growth temperature of the light-emitting layer 140 from decreasing or allows the growth temperature to stay relatively high. Moreover, due to the Ge dopant doped in the quantum well layers 142, the defects resulting from the overly low growth temperature do not occur in the quantum well layers 142, and the issue of the drastically reduced brightness of the light emitted from the light-emitting layer can be resolved. Further, the possibility that the resultant LED may not be able to emit light may be averted. As a result, the reliability of the light-emitting device 100 described in the present embodiment may be enhanced to some extent.

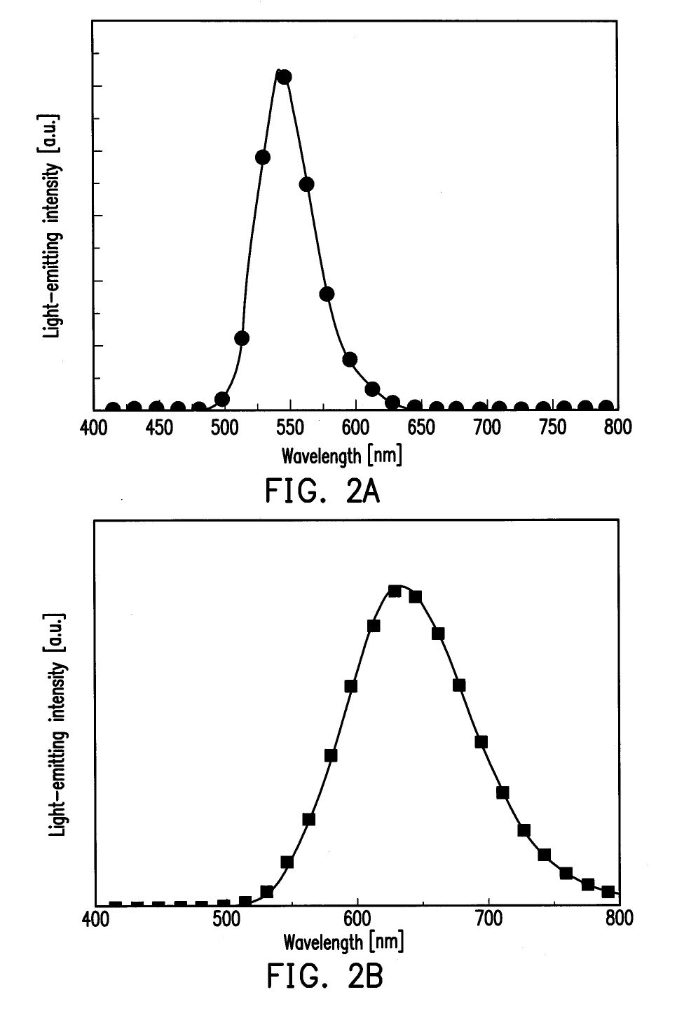

FIG. 2A illustrates wavelength distribution of a light-emitting device according to an embodiment of the invention. FIG. 2B illustrates wavelength distribution of a light-emitting device according to another embodiment of the invention. With reference to FIG. 2A and FIG. 2B, in light of said mechanism, the light-emitting device 100 (shown in FIG. 2A) capable of providing the yellow light (i.e., 550 nm) or the light-emitting device 100 (shown in FIG. 2B) capable of providing the red light (i.e., 650 nm) may be formed by means of the Ge dopant doped in the quantum well layers 142, so as to break the so-called green gap limitation. For instance, in the present embodiment, light emitted from the light-emitting layer 140 has a wavelength λ, ranging from about 365 nm to about 850 nm. It should be mentioned that the numerical range of each parameter provided above is exemplary and is not intended to limit the scope of the invention.

With reference to FIG. 1A, in addition to the substrate 110, the buffer layer 120, the first type doped semiconductor layer 130, the light-emitting layer 140, and the second type doped semiconductor layer 150, the light-emitting device 100 described in the present embodiment may further include a first electrode 160 and a second electrode 170. The first electrode 160 and the first type doped semiconductor layer 130 are electrically connected to each other, and the second electrode 170 and the second type doped semiconductor layer 150 are electrically connected to each other. To be specific, as shown in FIG. 1A, in the present embodiment, the electrodes in the light-emitting device 100 is arranged in a horizontal manner, for instance, which should however not be construed as a limitation to the invention. That is, a portion of the first type doped semiconductor layer 130 is not covered by the second type doped semiconductor layer 150, and the first electrode 160 is located on the portion of the first type doped semiconductor layer 130 that is not covered by the second type doped semiconductor layer 150. The second electrode 170 is located on a portion of the second type doped semiconductor layer 150. In another embodiment of the invention, the electrodes in the light-emitting device 100 may be arranged in a vertical manner.

Note that the material of the barrier layers 141 is not limited to be GaN. In another embodiment of the invention, the material of the barrier layers 141 may also be Ge:InGaN.

For instance, during the epitaxy process, parts of the Ge dopant doped in the quantum well layers 142 are diffused into the barrier layers 141, such that the barrier layers 141 are composed of Ge:GaN. Specifically, the concentration of the Ge dopant in the barrier layers 141 is often lower that that in the quantum well layers 142. No matter whether the barrier layers 141 contain the Ge dopant, the Ge dopant in the quantum well layers 142 is conducive to the reduction of the energy gap EG between the conduction band CB and the valance band VB.

To sum up, the Ge dopant in the quantum well layers allows the light-emitting device to emit the light with the long wavelength. Besides, according to an embodiment of the invention, the light-emitting layer may be formed in no need of significantly reducing the growth temperature or on the premise that the original growth temperature is maintained, and thereby the reliability of the light-emitting device may be enhanced.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A light-emitting device comprising:
a first type doped semiconductor layer;
a second type doped semiconductor layer; and
a light-emitting layer located between the first type doped semiconductor layer and the second type doped semiconductor layer, the light-emitting layer comprising a plurality of barrier layers and a plurality of quantum well layers, each of the quantum well layers being located between two adjacent barrier layers of the barrier layers, and the quantum well layers comprising a germanium dopant.

2. The light-emitting device as recited in claim 1, wherein a material of the quantum well layers comprises indium gallium nitride containing the germanium dopant (Ge:InGaN).

3. The light-emitting device as recited in claim 2, wherein a material of the barrier layers comprises gallium nitride (GaN).

4. The light-emitting device as recited in claim 2, wherein a material of the barrier layers comprises indium gallium nitride containing the germanium dopant (Ge:InGaN).

5. The light-emitting device as recited in claim 1, wherein the first type doped semiconductor layer is an n-type doped semiconductor layer, and the second type doped semiconductor layer is a p-type doped semiconductor layer.

6. The light-emitting device as recited in claim 1, wherein the first type doped semiconductor layer is a p-type doped semiconductor layer, and the second type doped semiconductor layer is an n-type doped semiconductor layer.

7. The light-emitting device as recited in claim 1, further comprising:
a substrate, wherein the first type doped semiconductor layer is located over the substrate and between the substrate and the light-emitting layer.

8. The light-emitting device as recited in claim 7, further comprising:
a buffer layer located between the substrate and the first type doped semiconductor layer.

9. The light-emitting device as recited in claim 1, further comprising:
a first electrode; and
a second electrode, wherein the first electrode and the first type doped semiconductor layer are electrically connected to each other, and the second electrode and the second type doped semiconductor layer are electrically connected to each other.

10. The light-emitting device as recited in claim 1, wherein the substrate comprises an aluminum oxide (Al₂O₃) substrate, a silicon (Si) substrate, a silicon carbide (SiC) substrate, a lithium aluminum oxide (LiAlO₂) substrate, a lithium gallium oxide (LiGaO₂) substrate, a gallium oxide (Ga₂O₃) substrate, a GaN substrate, a gallium phosphide (GaP) substrate, or a gallium arsenide (GaAs) substrate.

11. The light-emitting device as recited in claim 1, wherein light emitted from the light-emitting layer has a wavelength ranging from about 365 nm to about 850 nm.
